(19) United States
(12) Patent Application Publication
(10) Pub. No.: US 2022/0197013 A1
(43) Pub. Date: Jun. 23, 2022

(54) ELECTROMECHANICAL MICROSYSTEM

(71) Applicant: COMMISSARIAT A L'ENERGIE ATOMIQUE ET AUX ENERGIES ALTERNATIVES, Paris (FR)

(72) Inventors: Laurent MOLLARD, Grenoble Cedex 09 (FR); Stéphane NICOLAS, Grenoble Cedex 09 (FR); Damien SAINT-PATRICE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/558,085

(22) Filed: Dec. 21, 2021

(30) Foreign Application Priority Data
Dec. 21, 2020 (FR) 20 13823

(51) Int. Cl. G02B 26/08; G01L 9/00; B81B 3/00

(52) U.S. Cl. CPC G02B 26/0833; G01L 9/0041; B81B 2203/0127; B81B 2201/042; B81B 3/0045

(57) ABSTRACT

The invention relates to an electromechanical microsystem 1 including at least two electromechanical transducers 11 a and 11 b, a deformable diaphragm 12 and a cavity 13 hermetically containing a deformable medium 14 maintaining a constant volume under the action of an external pressure change. The deformable diaphragm forms a cavity wall and has at least one elastically deformable free area 121. The electromechanical transducers are configured so that their movement is a function of the said external pressure change, and vice versa, and so that two of them have opposing movements relative to each other. The free area cooperates with an external member 2 so that its deformation causes, or is caused by, a movement of the external member. The electromechanical microsystem is thus able to move the external member and/or sense a movement of this member, alternately towards the inside or outside of the cavity.

### TECHNICAL FIELD

This invention relates to the field of electromechanical microsystems. A particularly advantageous application is the actuation or movement of objects, in particular over relatively large distances. The invention is also applicable to the field of contact detection. It can thus be used to make sensors.

### STATE OF THE ART

In various applications, there may be a need to move microscopic or even nanoscopic objects and/or a need to sense the movements of such objects. Microsystems are available that allow this.

When these microsystems are actuators, their performance is assessed in particular with respect to the following parameters: the amplitude of the movement, the force deployed and the precision of the movement generated. When these microsystems are sensors, their performance is assessed in particular with respect to the following parameters: the ability to sense a movement over a large amplitude and the measurement accuracy.

In addition, whether the microsystems are actuators or sensors, proper performance is sought in terms of size, energy consumption and ability to operate on a frequency basis.

All known solutions have poor performance for at least one of these parameters. In general, existing microsystems do not perform well enough for a combination of these parameters.

One of the purposes of this invention is to provide an electromechanical microsystem that has improved performance over existing solutions, at least for one of the above-mentioned parameters, or that provides a better compromise regarding at least two of the above-mentioned parameters.

It is a further purpose of this invention to provide an electromechanical microsystem that allows upwards and downward movement of an associated external member or that allows sensing of upwards and downwards movement of an associated external member.

The other purposes, features and benefits of this invention will become apparent from the following description and accompanying drawings. It is understood that other benefits may be incorporated.

Abstract

To achieve at least one of the above purposes, according to one embodiment, an electromechanical microsystem is provided comprising:
at least two electromechanical transducers each comprising a part moving between an equilibrium, non-loaded position and an out-of-equilibrium, loaded position,
at least one deformable diaphragm, and
a deformable cavity delimited by walls.

At least one part of the deformable diaphragm forms at least one part of a first wall of the said cavity walls.

The cavity is configured to hermetically contain a deformable medium capable of maintaining a substantially-constant volume under the action of a change in external pressure exerted on the deformable medium through one of the cavity walls.

The moving part of each electromechanical transducer is configured so that its movement is a function of the said external pressure change or conversely that its movement causes an external pressure change.

At least one part of the deformable diaphragm has at least one area free to deform, preferably elastically, in response to the said external pressure change.

In addition, the electromechanical microsystem is such that:
the moving part of at least a first electromechanical transducer is configured so that its loading or an increase in external pressure causes its movement towards the outside of the cavity, and
the moving part of at least a second electromechanical transducer is configured so that its loading or a decrease in external pressure causes its movement towards the inside of the cavity.

The free area may be configured to cooperate with at least one external member so that its deformation causes, or is caused by, a movement of the external member, whereby the proposed solution is capable of moving the external member alternately towards the inside and outside of the cavity and/or sensing a movement of that member alternately towards the inside and outside of the cavity.

In particular, the proposed solution allows the electromechanical microsystem to move the external member into the cavity when the first transducer is loaded and out of the cavity when the second transducer is loaded.

Alternatively or additionally, the proposed solution allows the electromechanical microsystem to sense a movement of the external member towards the inside of the cavity by sensing an electrical current generated by the movement of the first transducer towards the outside of the cavity and a movement of the external member towards the outside of the cavity by sensing an electrical current generated by the movement of the second transducer towards the inside of the cavity.

Furthermore, the proposed solution allows the electromechanical microsystem to form a so-called long-travel actuator, i.e. typically allowing the external member to move over a stroke length of at least 30 μm or even 100 μm (10⁻⁶ metre). Similarly, the proposed solution allows the electromechanical microsystem to form a so-called long-travel sensor, typically allowing a movement of at least 30 μm or even 100 μm (10⁻⁶ metre) to be sensed.

The electromechanical microsystem as introduced above is thus capable of moving the external member or of sensing a movement of this member, while presenting, in an easily modulable way, depending on the applications in question, a sufficient capability in terms of amplitude of movement and/or a sufficient capability in terms of deployed force and/or a capability in terms of sensing movement over a sufficient amplitude and/or a sufficient capability to operate on a frequency basis and/or a size compatible with the applications in question, and/or a reduced energy consumption.

Optionally, the said at least two electromechanical transducers extend, on at least one of the cavity walls, at a distance from the free area of the deformable diaphragm. To this effect, the said at least two electromechanical transducers are disconnected from (or are not adjacent to) the free area of the deformable diaphragm.

Another aspect of the invention relates to an opto-electromechanical system or microsystem including at least one electromechanical microsystem as introduced above and at least one optical microsystem.

Another aspect of the invention relates to a process of manufacturing an electromechanical microsystem as introduced above, comprising, or even being limited to, ordinary microelectronic deposition and etching steps. The electromechanical microsystem can in fact be manufactured by ordinary microelectronic means, which gives its manufacturer all the benefits of using these means, including a great deal of latitude in terms of sizing, adhesion energy between the different deposits, thickness of the various deposits, etching area, etc.

Based on an example, the process of manufacturing the electromechanical microsystem system includes the following steps:
a step involving the forming, on a substrate, of at least a portion of at least two electromechanical transducers, and then
a step involving the deposition of the deformable diaphragm, and then
a step involving the forming of an open cavity on the deformable diaphragm, and then
a step involving the filling with the deformable medium and the closing of the cavity, and
a step involving the etching the substrate to form a front face (FAV) of the electromechanical microsystem.

### BRIEF DESCRIPTION OF THE FIGURES

The purposes, aims and features and benefits of the invention will become clearer from the detailed description of one embodiment thereof which is shown by the following accompanying drawings in which:

FIG. 1A is a schematic diagram of a cross-sectional view or section of an electromechanical microsystem comprising two electromechanical transducers according to a first embodiment of the invention.

FIG. 1B is a schematic diagram of a top view of the electromechanical microsystem according to the first embodiment of the invention, with one of the two transducers being disc-shaped, and the other being shaped like a ring surrounding the first transducer.

FIG. 1C is a schematic diagram of a cross-sectional view of an electromechanical microsystem according to a second embodiment of the invention.

FIG. 2 schematically represents a cross-sectional view or a section of an electromechanical microsystem according to the first embodiment of the invention.

FIG. 3 schematically represents a cross-sectional view or a section of the electromechanical microsystem according to the first embodiment of the invention at a first stage in its manufacturing process.

FIGS. 4 to 9 schematically represent a cross-sectional view or a section of the electromechanical microsystem according to the first embodiment of the invention at various stages in its manufacturing process.

FIG. 10A schematically represents a first embodiment of an opto-electromechanical microsystem comprising four electromechanical microsystems according to one embodiment of the invention.

FIG. 10B schematically represents a second embodiment of an opto-electromechanical microsystem comprising four electromechanical microsystems according to one embodiment of the invention.

FIGS. 11A and 11B each schematically represent other embodiments of an opto-electromechanical microsystem comprising four electromechanical microsystems according to one embodiment of the invention.

The drawings are given as examples and do not place any limit on the invention. They are schematic diagram representations intended to facilitate understanding of the invention and are not necessarily on the scale of practical applications. In particular, the thicknesses of the various layers, walls and members shown are not necessarily representative of reality. Also, the lateral dimensions of the piezoelectric elements, the free area of the diaphragm and/or the stops are not necessarily representative of reality, especially when considered in relation to each other.

### DETAILED DESCRIPTION

Before beginning a detailed review of embodiments of the invention, optional features are set forth below which may optionally be used in combination or alternatively.

According to one example, the said at least one first electromechanical transducer comprises at least one first disc-shaped electromechanical transducer of radius R1 and at least one second electromechanical transducer comprises at least one ring-shaped second electromechanical transducer with a radial extension of R2.

According to the preceding example, at least one first electromechanical transducer and at least one second electromechanical transducer are contained within the boundaries of a circular area of given radius referred to as the “total radius” and designated Rₜₒₜ, with the said circular area comprising two parts, a first disc-shaped part centred on the said circular area and a second ring-shaped part extending around the first part. The said at least one first electromechanical transducer is contained more particularly within the first part of the circular area and at least one second electromechanical transducer is contained more particularly within the second part of the circular area. The first part of the circular area has a radius R_{2/3} substantially equal to two thirds of the total radius and the second part of the circular area has an area E_{1/3} substantially equal to one third of the total radius.

According to the above example, the said at least one first electromechanical transducer further comprises at least one first ring-shaped electromechanical transducer, each first ring-shaped electromechanical transducer extending around the first disc-shaped electromechanical transducer and optionally around another first ring-shaped electromechanical transducer. The said at least one second electromechanical transducer comprises a plurality of second electromechanical transducers each ring shaped and arranged adjacent to and concentric with each other. The total radius Rₜₒₜ is preferably less than 900 μm, preferably less than 600 μm, and even more preferably less than 300 μm.

According to one example, the said at least one first electromechanical transducer comprises one first disc-shaped electromechanical transducer of radius R1 and at least one second electromechanical transducer comprises at least one second ring-shaped electromechanical transducer with a radial extension of R2.

According to the previous example, the radial extension R2 of the ring formed by the second electromechanical transducer is substantially twice as small as the radius R1 of the disc formed by the first electromechanical transducer.

In addition to or as an alternative to the above feature, the radius R1 of the disc formed by the first electromechanical transducer is at most equal to ⅔ of the sum Rₜₒₜ of the radius R1 of the disc formed by the first electromechanical transducer and the radial extension R2 of the ring formed by the second electromechanical transducer, and the radial extension R2 of the ring formed by the second electromechanical transducer is at most equal to ⅓ of the sum Rₜₒₜ of the radius R1 of the disc formed by the first electromechanical transducer and the radial extension R2 of the ring formed by the second electromechanical transducer.

The electromechanical transducers are preferably concentric.

According to one example, the free area is free to deform, preferably elastically, in response to the said external pressure change.

The electromechanical microsystem as introduced above is preferably free of any optical element, such as a lens, in particular a variable focus lens.

According to one example, with the free area configured to cooperate with at least one external member so that its deformation causes, or is caused by, a movement of the external member, the free area of the deformable diaphragm is configured to cooperate with the external member via a pin attached to the said free area, preferably in contact with the said free area, and more specifically in contact with an outer face of the free area.

According to the previous example, the pin may be attached in the centre of the free area of the deformable diaphragm. In this way, it is ensured that the movement of the pin is a translational movement perpendicular to the plane within which the cavity wall is contained, which is partly formed by the deformable diaphragm, when the diaphragm is not deformed.

The pin may be configured to cooperate with the external member via a guide integral with the external member, so as to allow automatic positioning of the external member on the pin.

The pin may be configured to be connected to the external member by adhesion or magnetism, the energy with which the pin adheres to the free area of the deformable diaphragm preferably being greater than that with which the pin adheres to the external member. A connection, possibly removable, between the pin and the external member is thus provided which is largely adjustable in terms of holding force.

According to one example, at least one part of the at least two electromechanical transducers forms a part of the cavity wall that is partially formed by the deformable diaphragm. The electromechanical microsystem according to this feature has a non-through structure, leaving the other walls of the cavity free so as to be able to carry out other functions thereon or so as to allow them to remain inert, for an increased integration capacity in particular in an opto-electromechanical microsystem.

According to one example, the said at least two electromechanical transducers extend, directly or indirectly, over the deformable diaphragm.

The said at least one second electromechanical transducer may be configured such that a movement of its moving part from its equilibrium position to its non-equilibrium position causes an increase in the external pressure acting on the deformable medium and the deformable diaphragm may be configured such that an increase in the external pressure acting on the deformable medium causes a deformation of the free area of the deformable diaphragm tending to move it away from the centre of the cavity (more specifically to move it away from a fixed cavity wall such as the wall opposite to the wall formed in part by the diaphragm). The electromechanical microsystem is thus configured so as to cause a movement of the external member in a first direction, corresponding to a movement of the external member away from the cavity (more specifically, away from a fixed cavity wall such as the wall opposite the wall formed in part by the diaphragm). In addition to the previous feature, the said at least one first electromechanical transducer may be configured such that a movement of its moving part from its equilibrium position to its non-equilibrium position causes an decrease in the external pressure acting on the deformable medium and the deformable diaphragm may be configured such that a decrease in the external pressure acting on the deformable medium causes a deformation of the free area of the deformable diaphragm tending to move it towards the centre of the cavity (more specifically to move it towards a fixed cavity wall such as the wall opposite to the wall formed in part by the diaphragm). The electromechanical microsystem is thus also configured so as to cause a movement of the external member in a second direction, this second direction tending to move it towards the external member of the cavity (more specifically, move it towards a fixed cavity wall such as the wall opposite the wall formed in part by the diaphragm).

The deformable diaphragm is preferably configured so that its free area is capable of being deformed with an amplitude of at least 50 μm, or even of at least 100 μm, or even of at least 1000 μm, in a direction perpendicular to the plane in which it primarily extends when at rest. Without tearing and/or without significant wear, the electromechanical microsystem thus offers the ability to meet the requirements of many different applications requiring a large amount of travel, the latter being defined by the technical field concerned.

The moving part of each electromechanical transducer may have a surface area at least twice as large as a surface area of the free area of the deformable diaphragm. The surface area of the moving parts of the transducers is preferably at least 5 times or even 10 times or even 20 times larger than the surface area of the free area 121 of the deformable diaphragm or even the surface area of the free areas of the deformable diaphragm.

Each electromechanical transducer may be a piezoelectric transducer, preferably comprising a PZT-based piezoelectric material.

At least one of the said at least two electromechanical transducers may be a statically-operating transducer. Alternatively or additionally, at least one of the said at least two electromechanical transducers may be a vibratory-operating transducer with at least one resonant frequency, the said at least one resonant frequency being preferably less than 100 kHz, and even more preferably less than 1 kHz.

The deformable medium hermetically contained in the cavity may comprise at least one, preferably liquid, fluid. The fluid preferably has a viscosity of about 100 cSt (1 cSt=10-6 m2/s) at ambient temperature and pressure.

According to a non-limiting embodiment example, the fluid has a compressibility of between 10⁻⁹ and 10⁻¹⁰ Pa⁻¹ at 20° C., for example, of about 10⁻¹⁰ Pa⁻¹ at 20° C., without these values being limiting.

The electromechanical microsystem may further include at least one lateral stop configured to:
guide the movement of an external member, when the free area is configured to cooperate with the said external member so that its deformation causes, or is caused by, a movement of the external member, and/or
engage a non-moving part of one of the electromechanical transducers.

The said at least one lateral stop may be supported by the cavity wall that is partially formed by the deformable diaphragm. According to an optional example, the said lateral stop extends away from the cavity.

It is thus possible to:
limit, in a controlled, reliable and reproducible way, the tilt of the external member during the movement of the moving part of each electromechanical transducer, and/or
allow self-positioning of the external member relative to the free area of the deformable diaphragm, and/or
protect the deformable diaphragm, and more particularly its free area, in particular from any possibility of being torn off, when the external member is transferred or stuck.

When the free area of the deformable diaphragm is configured to cooperate with the external member via a pin, the latter may have the following optional features which may optionally be used in combination or alternatively.

The pin may extend from the free area of the deformable diaphragm beyond the said at least one lateral stop.

Alternatively, the pin may extend from the free area of the deformable diaphragm within the at least one lateral stop.

The electromechanical microsystem according to either of the latter two features provides satisfactory adaptability with a wide variety of external members and applications.

The electromechanical microsystem may further comprise a so-called bottom stop supported by the cavity wall opposite the free area of the deformable diaphragm, the said bottom stop extending into the cavity towards the free area. It has a shape and dimensions configured to limit the deformation of the free area of the deformable diaphragm so as to protect the deformable diaphragm, and more particularly its free area, from any possibility of being torn off, in particular when the external member is transferred or stuck. Furthermore, the so-called bottom stop can be shaped to limit the contact surface between the diaphragm and the cavity wall opposite the free area of the deformable diaphragm. Alternatively or cumulatively, the bottom stop may be shaped to limit the contact area between the diaphragm and the cavity wall opposite the free area of the deformable diaphragm. This prevents the diaphragm from adhering to this wall.

The electromechanical microsystem as introduced above may further include a plurality of deformable diaphragms and/or a plurality of free areas per deformable diaphragm.

The said at least one optical microsystem of the opto-electromechanical system as introduced above may include at least one, preferably silicon-based, mirror also referred to as a micromirror.

According to one example, the opto-electromechanical system is configured such that the movement of the moving part of each of the said at least two electromechanical transducers causes a movement of the at least one mirror.

Alternatively or additionally, the opto-electromechanical system may include a plurality of electromechanical microsystems each having a free area arranged opposite a part of the same optical microsystem, such as a mirror. Preferably, the electromechanical microsystem cooperates with the mirror in an area that is not in the centre of the mirror but, for example, in a corner of the mirror. This results in an opto-electromechanical system or microsystem with a large capacity to adapt its optical orientation. Each electromechanical microsystem allowing the part of the optical microsystem opposite which it is arranged to be moved alternately towards the inside and towards the outside of the cavity, a doubling of the amplitude of movement of the optical microsystem can be achieved relative to an electromechanical microsystem allowing only a movement towards the inside of the cavity or towards the outside of the cavity.

The term “electromechanical microsystem” means a system including at least one mechanical element and at least one electromechanical transducer made on a micrometric scale by microelectronic means. The mechanical element can be set in motion (actuated) by a force generated by the electromechanical transducer. The latter can be powered by electrical voltages generated with nearby electronic circuits. Alternatively or additionally, the electromechanical transducer can sense a movement of the mechanical element; the electromechanical microsystem then acts as a sensor.

A “microsystem” is a system whose external dimensions are less than 1 centimetre (10⁻² metres) and preferably less than 1 millimetre (10⁻³ metres).

Most often, an electromechanical transducer acts as an interface between the mechanical and electrical domains. However, the term “electromechanical transducer” refers both to a piezoelectric transducer and a thermal transducer, the latter acting as an interface between the mechanical and thermal domains. An electromechanical transducer may comprise a part moving between an equilibrium, non-loaded position and an out-of-equilibrium, loaded position. When the transducer is piezoelectric, the loading is electrical. When the transducer is thermal, the loading is thermal.

When reference is made to the centre of the cavity, this centre is defined geometrically as the centre of a cavity with an undeformed free area of the deformable diaphragm.

“Below” and “above” mean “not greater than” and “not less than”, respectively. Equality is excluded by the use of the terms “strictly less than” and “strictly greater than”.

A parameter that is “substantially equal to/above/below” a given value means that the parameter is equal to/above/below the given value within plus or minus 20% or even 10% of that value. A parameter that is “substantially between” two given values means that the parameter is at least equal to the smaller given value within plus or minus 20% or 10% of that value and at most equal to the larger given value within plus or minus 20% or 10% of that value.

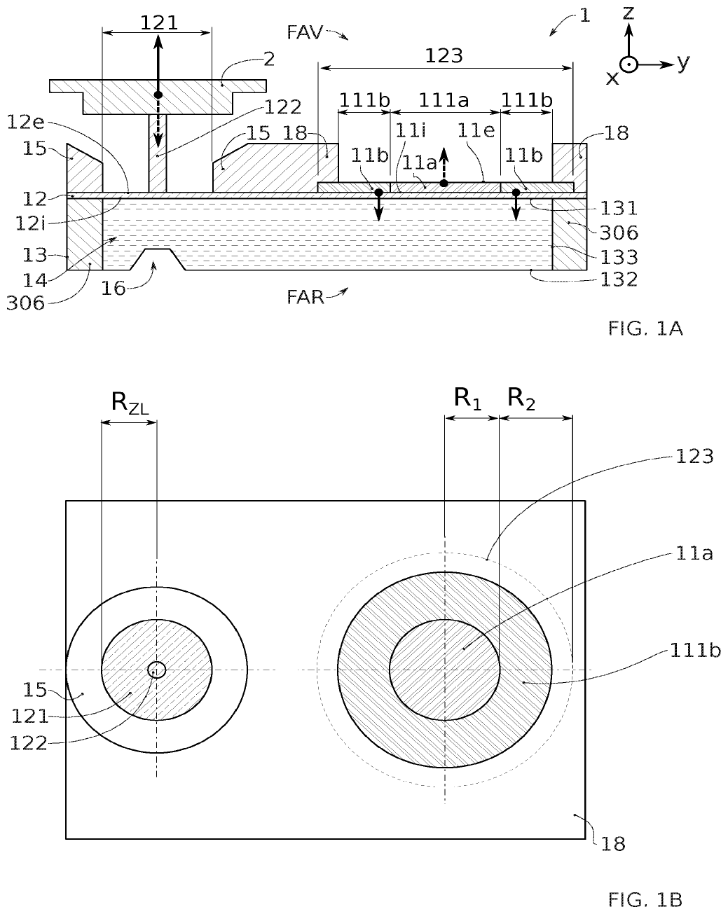

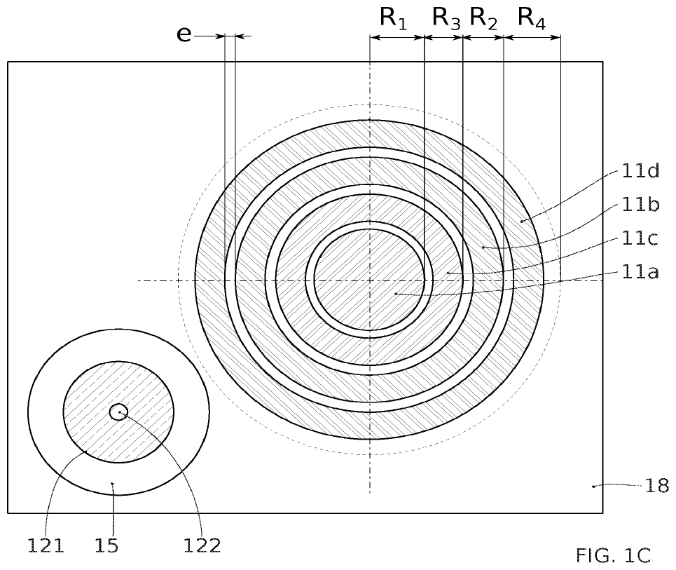

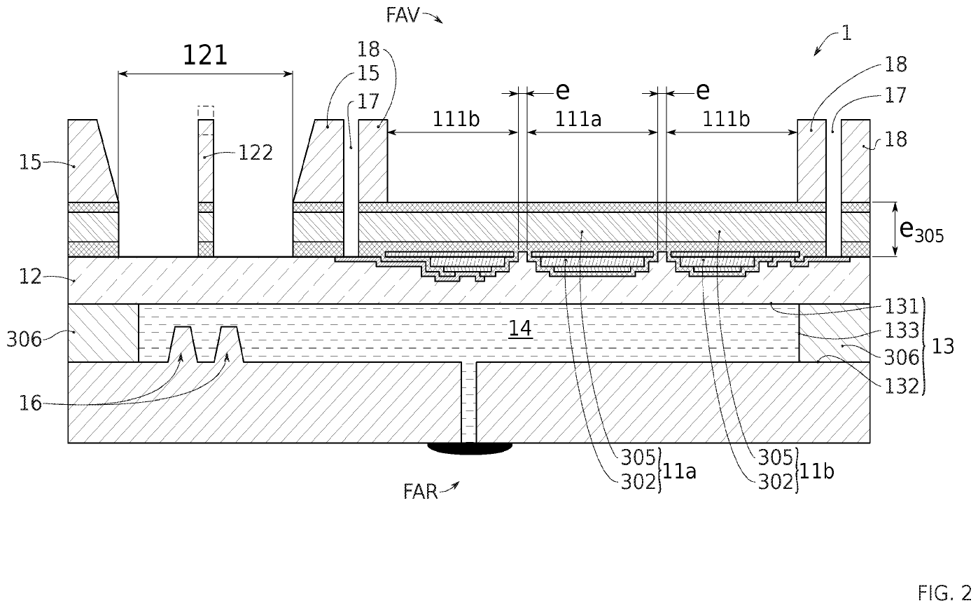

FIG. 1A is a schematic diagram of a cross-sectional view or section of an electromechanical microsystem 1 according to a first embodiment of the invention. FIG. 1A shows two electromechanical transducers 11a and 11b, a deformable diaphragm 12 and a cavity 13 configured to hermetically contain a deformable medium 14.

This schematic diagram may represent a structure with no rotational or revolutionary symmetry about an axis perpendicular and centred with respect to the surface of the deformable diaphragm as shown, as well as a structure extending, for example, in a substantially invariant manner, perpendicularly to the shown cross-sectional view and symmetrical for a first part with respect to a plane perpendicular and centred with respect to the referenced area 121 and for a second part with respect to a plane perpendicular and centred with respect to the referenced area 111a.

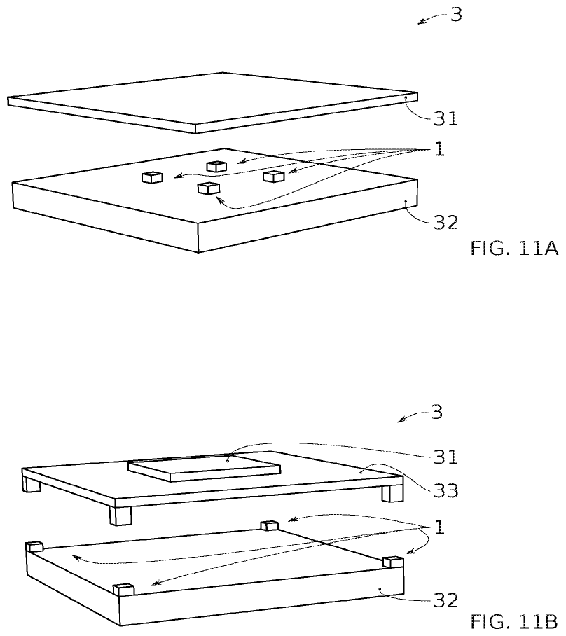

Before further describing the various embodiments of the invention shown in the appended figures, it should be noted that each of these illustrations schematically represents an embodiment of the electromechanical microsystem according to the invention which has a non-through structure. More particularly, in the various embodiments shown, each electromechanical transducer 11a and 11b and the deformable diaphragm 12 are both located on the front FAV of the electromechanical microsystem 1. This type of structure is particularly advantageous in that the rear FAR of the electromechanical microsystem 1 can participate only passively, and in particular without deforming, in the actuator and/or sensor function of the electromechanical microsystem 1. More particularly, the rear FAR of an electromechanical microsystem 1 with a non-through structure according to the invention may in particular form a face by which the electromechanical microsystem 1 may be easily fitted to a support (referenced 32 in FIGS. 11A and 11B) and/or may form a face by which the electromechanical microsystem may be easily further functionalised.

However, the invention is not limited to electromechanical microsystems with a non-through structure. In its broadest acceptance, the invention also relates to so-called through-structured microsystems 1 in which at least one of the transducers 11a and 11b and the deformable diaphragm 12 are arranged on mutually distinct walls of the cavity 13, regardless of whether these walls are adjacent or opposite each other.

Each electromechanical transducer 11a, 11b as shown in FIGS. 1A and 1B includes at least one moving part 111a, 111b. The latter is configured to move or be moved between at least two positions. The first of these positions is an equilibrium position reached and maintained when the transducer 11a, 11 b is not loaded, either by an electrical voltage supplying it or by a force moving it away from its equilibrium position. The second of these positions of the moving part 111a, 111b of each of the two transducers 11a, 11 b is reached when the transducer is loaded, either by an electrical voltage supplying it or by a force moving it away from its equilibrium position. Each electromechanical transducer 11a, 11b may be held in either of the first and second positions described above, and thus exhibit binary behaviour, or be held in any intermediate position between its equilibrium position and its position of greatest deformation, or greatest deflection, from equilibrium.

In the example shown in FIGS. 1A and 1B, when an electromechanical transducer 11a, 11 b is not loaded, its moving part 111a, 111b extends primarily in a plane parallel to the plane xy of the orthogonal reference frame xyz shown in FIG. 1A.

At least one, and preferably each, electromechanical transducer 11a, 11b is preferably a piezoelectric transducer. It is known that such a transducer converts an electrical power supply into a movement of its moving part 111a, 111b from its equilibrium position to a non-equilibrium position and/or converts a movement of its moving part 111a, 111b from its equilibrium position to a non-equilibrium position into an electrical signal. It is thus apparent from this example, but potentially remains true for each of the other contemplated embodiments of the electromechanical microsystem 1 according to the invention, that the latter can operate as an actuator and/or as a sensor. As an actuator, it may allow an external member 2 to be moved up and down, as shown in FIG. 1A. As a sensor, it may allow the sensing of a movement, in particular a vertical movement, of the external member 2 upwards and downwards, as also shown in FIG. 1A. To allow the generated signal to be a function of the movement of the external member 2, and in particular of its movement amplitude, it is preferable for the surface of the free area 121 to be larger than the surface of the moving parts 111a, 111b of the electromechanical transducers 11a, 11 b which is in contact with the deformable diaphragm 12. In the following, for the sake of simplicity, the electromechanical microsystem 1 will be described essentially as an actuator, without, however, excluding its ability to provide alternatively or additionally, a sensor function.

At least one, if not each, electromechanical transducer 11a, 11 b is even more preferably a piezoelectric transducer comprising a PZT (Lead Titano-Zirconate) based piezoelectric material. In this case, the moving part 111a, 111b of the transducer 11a, 11 b is able to move with a more significant movement (due to the piezoelectric coefficient d31) than with many other piezoelectric materials. However, since PZT is a ferroelectric material, such piezoelectric transducers each preferentially operate in a single actuation direction (movement in a single direction of their moving part 111a, 111b) regardless of the polarity of its power supply, whereas a piezoelectric transducer based on a non-ferroelectric material can preferentially operate in both directions (movement in two opposite directions of their moving part 111a, 111b). Alternatively or additionally, at least one or each electromechanical transducer 11a, 11b may be a piezoelectric (non-ferroelectric) transducer based on a material suitable for allowing its moving part 111a, 111b to move in opposite directions relative to its equilibrium position depending on the polarity of its power supply. Such a material is, for example, an aluminium-nitride-based material (AlN).

Alternatively or additionally, at least one or each electromechanical transducer 11a, 11b may be or include a thermal transducer.

The deformable diaphragm 12 may be polymer based, and is preferably PDMS (polydimethylsiloxane) based. The properties of the deformable diaphragm 12, in particular its thickness, surface area and shape, can be configured to provide the deformable diaphragm 12, and in particular an area 121 of the diaphragm that is free to deform, with an expected stretchability, in particular depending on the intended application.

The cavity 13 as shown in particular in FIG. 1A more particularly has walls 131, 132, 133 hermetically containing the deformable medium 14. In the examples shown, the wall 132 of the cavity 13 forms the rear FAR of the electromechanical microsystem 1. The wall 131 opposite the wall 132 is formed at least in part by at least a part of the deformable diaphragm 12. The wall 131 is thus deformable. The wall 131 is hereinafter referred to as the first wall. It is located on the front FAV of the electromechanical microsystem 1. At least one side wall 133 joins the walls 131 and 132 together. This side wall 133 may include or consist of at least one spacer 306 as shown in FIG. 1A, the role of which is detailed below. It will be noted that the sealing of the cavity 13 calls for the deformable diaphragm 12 to itself be impermeable, or rendered impermeable, in particular at its free area 121.

It should also be noted that, in order to more easily ensure the hermetic sealing of the cavity 13:
the first wall 131 of the cavity is preferably entirely formed or covered by at least the deformable diaphragm 12 and/or
each electromechanical transducer 11a and 11b extends over the entire extension of the deformable diaphragm 12, being in direct or indirect contact therewith.

The walls 132, 133 preferably remain fixed as the diaphragm is deformed.

The deformable medium 14 is in turn capable of maintaining a substantially constant volume under the action of an external pressure change. In other words, it can be an incompressible or weakly compressible medium the deformation of which preferably requires little energy. For example, it is a liquid.

Since at least part of the wall 131 of the cavity 13 is formed by at least part of the deformable diaphragm 12, it is understood that any change in external pressure exerted on the deformable medium 14 can be compensated for by a substantially proportional deformation of the deformable diaphragm 12, and more particularly its free area 121, and/or by a movement of the moving part 111a, 111b of one of the electromechanical transducers 11a, 11 b. When one of the transducers 11a, 11 b is loaded, this compensation is more particularly related to a conversion of the external pressure change exerted on the deformable medium 14 into a stretching of the deformable diaphragm 12. It is understood that, for the sake of reproducibility of the actuation or motion sensing offered by the electromechanical microsystem 1 according to the invention, it is preferable for any deformation of the deformable diaphragm 12 to be elastic, and not plastic, to ensure that the deformable diaphragm 12 returns to the same state of least stretch, or maximum relaxation, whenever it is no longer loaded.

The deformable medium 14 may more particularly include at least one, preferably liquid, fluid. The parameters of the liquid will be adjusted according to the intended applications. This ensures that any change in external pressure exerted on the deformable medium 14 causes a substantially proportional deformation of the free area 121 of the deformable diaphragm 12. The fluid may be a liquid or liquid based, such as oil, or may be a polymer or polymer based. According to one example, the fluid is based on or consists of glycerine. In this way, in addition to a substantially proportional deformation of the diaphragm 12, the deformable medium 14 is able to occupy, in particular, the volume created by stretching the free area 121 of the deformable diaphragm 12 opposite the centre of the cavity 13.

It is understood from the above that the electromechanical microsystem 1 is configured so that each movement of an electromechanical transducer 11a, 11 b causes a change in the external pressure exerted on the deformable medium 14, in order to provide the actuator function of the electromechanical microsystem 1, and conversely, in order to provide the sensor function of the electromechanical microsystem 1. More particularly, when the electromechanical microsystem 1 acts as an actuator, at least a part of one of the electromechanical transducers 11a and 11b is loaded so as to exert an external pressure change on the deformable medium 14 and thereby cause the deformation of the deformable diaphragm 12. Conversely, when the electromechanical microsystem 1 acts as a sensor, the deforming of the diaphragm 12 exerts an external pressure change on the deformable medium 14 which causes a movement of the moving part 111a, 111b of one of the electromechanical transducers 11a, 11b.

As shown in FIG. 1A, the electromechanical microsystem 1 may be such that the free area 121 of the deformable diaphragm 12 is configured to cooperate with an external member 2. In this way, the deformation of the free area 121 causes, or is caused by, a movement of the external member 2. It is thus through the free area 121 of the deformable diaphragm 12 that the microsystem 1 moves the external member 2 or senses a movement of the external member 2. Thus, when the microsystem 1 acts as an actuator, the activation of one of the electromechanical transducers 11a, 11b deforms the diaphragm 12 which moves the member 2. Conversely, when the microsystem 1 acts as a sensor, if an external member 2 is pressed against the diaphragm 12 or the diaphragm 12 is pulled by an external member 2, the diaphragm 12 is deformed, which moves one of the moving parts of the electromechanical transducers 11a, 11b and then ultimately generates a signal that may depend on this movement.

More particularly, the cooperation between the free area 121 of the deformable diaphragm 12 and the external member 2 may be achieved via a finger, also referred to as a pin 122, which is attached to the free area 121. The terms “finger” and “pin” may be interchanged. The term “pin” is not limited to parts with a constant cross-section, let alone cylindrical parts.

As shown in FIG. 1A, the pin 122 may be more particularly attached to the centre of the free area 121 of the deformable diaphragm 12, or more generally symmetrically about the extension of the free area 121 of the deformable diaphragm 12. In this way, the pin 122 is moved, through the elastic deformation of the free area 121, in a direction that is controlled and substantially vertical or albeit only slightly tilted with respect to the vertical, during its movements. The lateral movement of the pin 122 is thus advantageously limited.

Additionally or alternatively, the external member 2 may be structured to include a guide through which the external member 2 cooperates with the pin 122. This guide can also help to prevent the pin 122 from tilting when it moves. It will be seen later that the limitations thus achieved in terms of lateral deflection of the pin 122 may be further enhanced by the provision of at least one lateral stop 15 extending from a part of the wall 131 located outside the free area 121 of the deformable diaphragm 12.

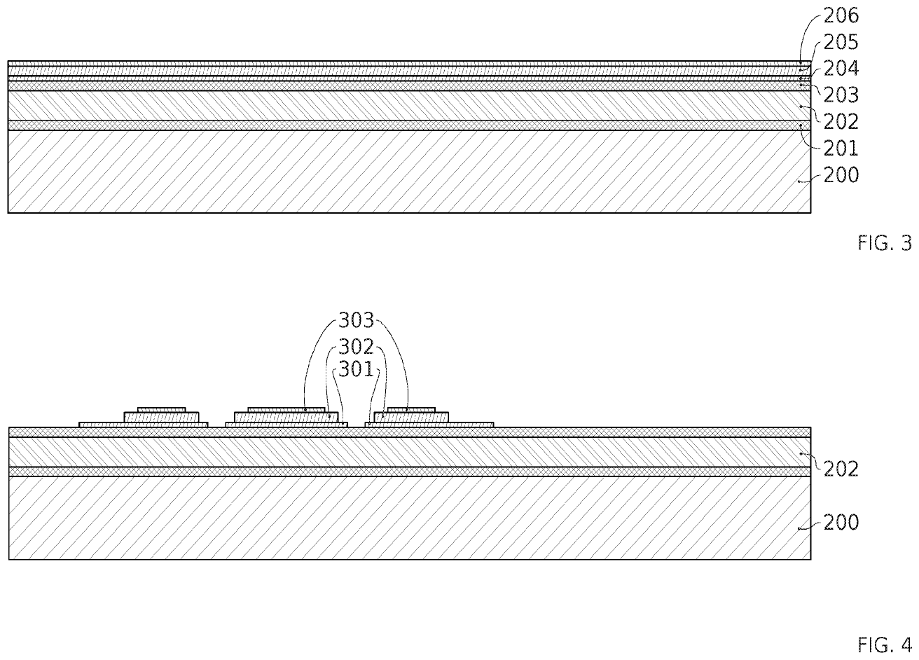

In a non-limiting way, the pin 122 being bonded to or magnetized to the external member 2 may allow the pin 122 and the external member 2 to be made integral with each other. The energy with which the pin 122 adheres to the free area 121 of the deformable diaphragm 12 is preferably greater than that with which the pin 122 adheres to the outer member 2. It will be seen, during the description of the manufacturing process of the electromechanical microsystem 1 shown in FIG. 2 that the energy with which the pin 122 adheres to the free area 121 can be a result of ordinary technological steps in the field of microelectronics. Since this adhesion energy can thus be estimated or measured, it is easy to obtain by bonding, for example using an ad hoc resin or through magnetisation, for example, adhesion that is of lower energy than the energy with which the pin 122 adheres to the deformable diaphragm 12. It is thus understood that the connection between the pin 122 and the external member 2 can thus be largely adjusted in terms of holding force. This modularity may make it possible, in particular, to make the connection between the pin 122 and the external member 2 removable, for example to allow the same electromechanical microsystem 1, according to the invention, to be arranged successively with several external members 2 with each of which it would be connected and then disconnected.

As shown in FIG. 1A, each electromechanical transducer 11a, 11b may form a part of the first wall 131 of the cavity 13. Each of the electromechanical transducers 11a and 11b and the deformable diaphragm 12 are thus positioned on the same side of the cavity 13. Structures with this feature are advantageously non-penetrating, as mentioned above.

In this non-limiting example, the diaphragm 12 has an inner face 12i configured to be in contact with the deformable medium 14 and an outer face 12e. The inner face 12i forms at least a part of the first wall 131 of the cavity 13. In order to easily ensure the sealing of the cavity 13, the inner face 12i of the deformable diaphragm 12 forms the entire first wall 131 of the cavity 13. Each electromechanical transducer 11a, 11b, more specifically the moving part 111a, 111b of the latter, has an inner face 11i facing, and preferably in contact with, the outer face 12e of the diaphragm 12. Each electromechanical transducer 11a, 11 b also has an outer face 11e, opposite the inner face 11i, and facing the outside of the electromechanical microsystem 1. In order to easily ensure the sealing of the cavity 13, the inner face 11i of each electromechanical transducer 11a, 11b is preferably entirely in contact with the outer face 12e of the diaphragm 12. One or more intermediate layers may be provided between the outer face 12e of the diaphragm 12 and the inner face 11i of each transducer 11a, 11b. The electromechanical microsystem 1 is configured such that the movement of the moving part 111a, 111b of each electromechanical transducer 11a, 11 b causes a deformation of the diaphragm 12 and thus of the first wall 131 which encloses the medium 14.

Note that in FIG. 1A:
each electromechanical transducer 11a, 11 b extends over the deformable diaphragm 12, and
the deformable diaphragm 12 separates each electromechanical transducer 11a, 11b, preferably over their entire extension, from the deformable medium 14.

In addition, each electromechanical transducer 11a and 11b can advantageously be integral with the deformable diaphragm 12 over an area 123 located outside the free area 121, and more particularly over an area 123 distant from the free area 121, so that any movement of the moving part 111a, 111b of each transducer 11a, 11b causes, in particular in this area 123, the deformable diaphragm 12 to be stretched or relaxed. Thus, in the example shown in FIG. 1A, when the first transducer 11a is loaded to move upwards (as shown by the dashed arrow extending from the moving part 111a of the first transducer 11a), a decrease in the external pressure exerted on the deformable medium 14 is observed, which causes the deformable diaphragm 12 to stretch downwards, i.e., towards the centre of the cavity 13.

Still, in the example shown in FIG. 1A, when the second transducer 11b is loaded to move downwards (as shown by the dashed arrow extending from the moving part 111b of the second transducer 11b), an increase in the external pressure exerted on the deformable medium 14 is observed, which causes the deformable diaphragm 12 to stretch upwards, i.e., away from the centre of the cavity 13. It should be noted here that this connection between the second transducer 11b and the deformable diaphragm 12 is only preferential for the shown microsystem, insofar as the moving part 111b of the second transducer 11b is intended to press against the deformable diaphragm 12 when the second transducer 11b is loaded and/or insofar as the deformable diaphragm 12 has a natural tendency to remain in contact with the moving part 111b of the second transducer 11b when the latter is not pressing against the deformable diaphragm 12.

It should be noted, however, that in its equilibrium position, the moving part 111a, 111b of an electromechanical transducer 11a, 11 b, or even of each transducer, cannot be flat, but may instead exhibit a deflection, known as the equilibrium deflection, which does not detract in any way, in terms of amplitude, from the movement or deflection capability of the transducer 11a, 11 b.

With reference to FIGS. 1A and 1B, a cover 18 may be provided which is configured, and which is more particularly sufficiently rigid, to hold:
the diaphragm 12 around the area 123 over which the first and second transducers 11a and 11b extend, the diaphragm 12 thus being partly located between the cover 18 and the deformable medium 14, and
the non-moving part of the second electromechanical transducer 11b over which it extends.

The cover 18 extends in the xy-plane, for example. It has at least one opening that defines the area in which the moving parts of the said at least two electromechanical transducers 11a and 11b extend. The cover 18 may extend over the entire first face 131 of the cavity 13, when projected in the xy plane, with the exception of an area located around the free area 121 of the deformable diaphragm 12. In this area located around the free area 121 of the deformable diaphragm 12, lateral stops 15 are provided (see below) and which may extend the cover 18.

As shown in FIG. 1A, at least one spacer 306 may be provided which essentially has the role of contributing with the cover 18 to holding the non-moving part of the second transducer 11b. Indeed, the said at least one spacer 306 shown in FIG. 1A extends at least in line with a part of the cover 18 which, on the right of the figure, covers the non-moving part of the second electromechanical transducer 11b, this non-moving part thus being pinched between the cover 18 and the spacer 306. The said at least one spacer 306 may further extend past a part of the at least one side stop 15, and in particular past a part of the said at least one most eccentric side stop 15, as shown in FIG. 1A. The said at least one spacer 306 may form at least a part of the side wall 133 of the cavity 13. Note that it is also possible to provide a spacer at a part of the cover 18 which is centred relative to the extension of the cavity 13 in the (x,y) plane, and in particular at such a part of the cover 18 which also extends over the non-moving part of the second transducer 11b.

FIG. 1B shows the partial covering of the deformable diaphragm 12 by the two electromechanical transducers 11a and 11b according to the first embodiment of the invention. The first transducer 11a is shaped like a disc with a radius noted R1. The second transducer 11b is shaped like a ring extending around the disc 11a over a radial extension R2. The disc 11a and the ring 11b are preferably concentric. The disc 11a and the ring 11b may be, as shown, adjacent to each other, the ring 11b then having a radial extension equal to R2. Alternatively, the disc 11a and the ring 11b may be slightly spaced apart, with the ring 11b then having a radial extension slightly less than R2.

The radius R1 of the disc 11a is at most two thirds of the total radius R1+R2. The radial extension R2 of the area extending around the disc 11a is at most one third of the total radius R1+R2. This ensures that the first electromechanical transducer 11a and the second electromechanical transducer 11b have opposing movements relative to each other, when loaded.

The total radius R1+R2 is preferably less than 900 μm, preferably less than 600 μm, and preferably less than 300 μm.

When the first and second transducers 11a and 11b are spaced apart, the radial extension of this spacing is, for example, between 1 and 100 μm, and is typically 10 μm.

It is understood here that as each electromechanical transducer 11a, 11 b has its own moving part 111a, 111b, the moving part of one of the two transducers can be loaded independently from, and in particular alternately to, the moving part of the other transducer. It is then advantageous for the deformation of the moving part 111a of the first electromechanical transducer 11a to oppose, and more particularly be in an opposite direction to, in the z-axis direction, the deformation of the moving part 111b of the second electromechanical transducer 11b. Indeed, it is then possible, even when each of the two transducers 11a and 11b includes a PZT-based piezoelectric transducer, to alternately cause a movement away from and towards the external member 2, depending on which of the two transducers 11a and 11b is loaded. For example, the first electromechanical transducer 11a is configured to move upwards, i.e. away from the centre of the cavity 13, when loaded and the second electromechanical transducer 11b is configured to move downwards, i.e. towards the centre of the cavity 13, when loaded.

In addition, it is advantageous for the radial extension R2 of the second transducer 11b to be about half the radius R1 of the first transducer 11a. In such a configuration, the moving part 111a of the first transducer 11a and the moving part 111b of the second transducer 11b can be moved or deflected with a substantially equal amplitude, when the transducers are alternately and substantially equally loaded.

Also when the partial overlap of the deformable diaphragm 12 by the two transducers 11a and 11b is as shown in FIG. 1B and the transducers 11a and 11b are piezoelectric transducers each including a PZT-based piezoelectric material, the radius R_{ZL} of the free area 121 of the deformable diaphragm 12 may be substantially equal to 100 μm and the radius R1 of the first electromechanical transducer 11a may be substantially equal to 200 μm. The references R_{ZL} and R1 are shown in FIG. 1B. Still when the partial overlap of the deformable diaphragm 12 by the two transducers 11a and 11b is as shown in FIG. 1B and the transducers 11a and 11b are piezoelectric transducers each including a PZT-based piezoelectric material, but with reference to FIG. 2 discussed in more detail below, each electromechanical transducer 11a and 11b more particularly includes a beam 305 and a PZT-based piezoelectric element 302, with the latter being configured to cause deflection of the beam 305. The thickness of the piezoelectric element 302 may be substantially equal to 0.5 μm and the thickness of the beam 305 is, for example, between a few microns and several tens of microns; for example, it is substantially equal to 5 μm. In such a configuration, when R1 is equal to 200 microns and R2 is equal to 100 microns, the amplitude of movement of the moving parts 111a, 111b of the transducers 11a and 11b may, for example, reach a value equal to a few microns, in particular when a voltage of a few tens of volts is applied across one or other of the transducers 11a and 11b.

It is immediately apparent from FIG. 1B that the free area 121 of the diaphragm 12 is spaced from, or is separated from, the area 123 over which the two transducers 11a and 11 b overlap the diaphragm 12. In other words, the free area 121 and the area 123 do not overlap each other nor are they adjacent to each other. A distance is therefore left between area 121 and area 123.

It is again immediately apparent from FIG. 1B that the free area 121 of the diaphragm 12 is off-centred with respect to the area 123 over which the two transducers 11a and 11b cover the diaphragm 12. This feature is related to the fact that the first transducer 11a is disc-shaped, and is therefore solid.

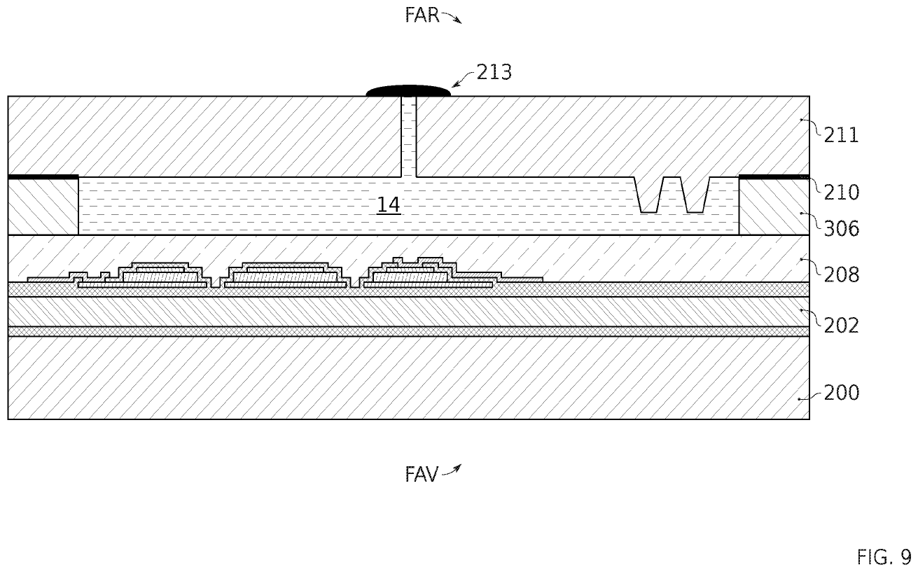

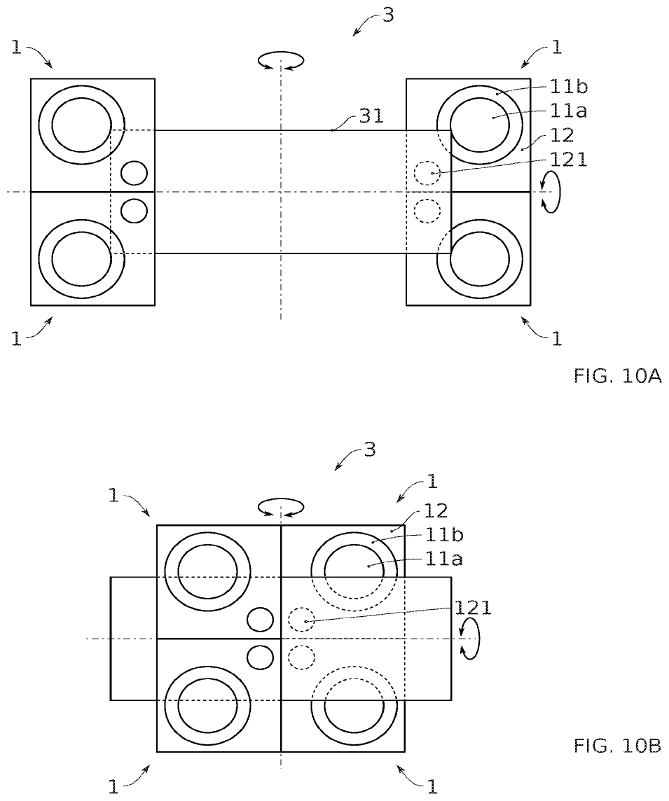

It is again apparent from FIG. 1B that the at least one lateral stop 15 may be shaped like a ring extending from the first cavity wall 131 and around the free area 121 of the diaphragm 12. Similar observations can be made on the basis of FIG. 10.

FIG. 10 shows the partial covering of the deformable diaphragm 12 by four electromechanical transducers 11a, 11b, 11c and 11d according to a second embodiment of the invention. FIG. 10 is more particularly a top view of the second embodiment of the electromechanical microsystem according to the invention. In this second embodiment, the said at least one first electromechanical transducer 11a comprises at least one disc-shaped electromechanical transducer of radial extension R1; The said at least one second electromechanical transducer 11b comprises at least one electromechanical transducer shaped like a ring extending around the disc 11a over a radial extension R2, as in the first embodiment described above. However, in contrast to the first embodiment described above, the said at least one first electromechanical transducer 11a and/or the said at least one second electromechanical transducer 11b according to the second embodiment of the invention may comprise one or more further electromechanical transducers. Thus, according to the example illustrated in FIG. 10, the electromechanical microsystem 1 may comprise a third ring-shaped electromechanical transducer 11c and extending between the disc 11a and the ring 11b over a radial extension area R3, and a fourth ring-shaped electromechanical transducer 11d extending around the ring 11b over a radial extension area R4. The transducers 11a, 11b, 11c and 11 d according to the second embodiment of the invention are preferably concentric. The radially successive electromechanical transducers are either spaced apart or adjacent to each other. Their moving parts are, for example, separated from each other by a distance noted e in FIG. 10. This distance can be compared to the one also noted e in FIG. 2 detailed below. However, in the latter Figure, the distance e is intended more to show that the piezoelectric elements 302 of adjacent transducers must not to touch each other in order to be electrically isolated from each other, than to show that the transducers can be spaced apart, even when they are arranged concentrically to each other.

The deformation of the moving parts of the transducers 11a and 11c can advantageously oppose the deformation of the moving parts of the transducers 11b and 11d. For this purpose, the transducers 11a and 11c may be contained within a disc of radius less than ⅔ of the total radial extension R1+R3+R2+R4 of the transducers.

Alternatively, the transducer 11a may be contained within a first circular area of radius less than two-thirds of the total radial extension R1+R3+R2+R4 of the transducers and the other three transducers 11b, 11c and 11 d may extend beyond the first circular area over an annular area with a radial extension less than one-third of the total radial extension R1+R3+R2+R4 of the transducers.

Another alternative involves considering that the three transducers 11a, 11b and 11c are located in the first circular area with a radius of less than two thirds of the total radial extension R1+R3+R2+R4 and that the fourth electromechanical transducer 11d is located in the annular area with a radial extension of less than one third of the total radial extension R1+R3+R2+R4 of the transducers extending around the first circular area.

As already discussed above with reference to the embodiment shown in FIG. 1B, even when each of the transducers 11a, 11b, 11c and 11 d includes a PZT-based piezoelectric transducer, it is possible to alternately cause a movement away from and towards the external member 2, depending on which of the electromechanical transducers 11a, 11 b, 11c and 11 d is loaded. It is further understood that an additional advantage, with respect to the first embodiment schematically shown in FIGS. 1A and 1B, is that the second embodiment may make it possible to obtain at least two mutually different distances when moving away from the external member 2 and/or at least two mutually different distances when moving towards the external member 2. The electromechanical microsystem 1 according to the second embodiment of the invention thus forms a step-by-step actuator, capable of moving the external member 2 between at least four elevation and/or approach positions, in particular when each of the transducers 11a, 11b, 11c and 11d operates in a binary mode.

It should be noted here that the electromechanical microsystem 1 according to the second embodiment is not limited to the example shown comprising three transducers 11b, 11c and 11 d each having an annular shape. More particularly, the second embodiment extends to a case comprising two annular-shaped transducers and a case comprising more than three annular-shaped transducers.

It should be noted that, regardless of which of the embodiments of the electromechanical microsystem according to the invention is used, each electromechanical transducer 11a, 11b, 11c, 11d is not limited to an annular or disc shape, but may take on other shapes, and in particular a hollow or solid, oblong, oval, triangular, rectangular, etc. shape.

In particular, when the partial overlap of the deformable diaphragm 12 by the electromechanical transducers is as shown in one of FIGS. 1B and 1C and each electromechanical transducer is a piezoelectric transducer comprising a PZT-based piezoelectric material, it is advantageous for the moving part of each electromechanical transducer to have a surface area at least 2 times larger than the surface area of the free area 121 of the deformable diaphragm 12. The deformable diaphragm 12 is therefore configured such that its free area 121 is capable of being deformed with an amplitude of at least 50 μm, or about 100 μm, or even several hundred μm. The surface area of the moving parts of the transducers 11a and 11 b shown in FIG. 1B, or of the transducers 11a, 11 b, 11c and 11 d shown in FIG. 1C, is at least 5 times or even 10 times or even 20 times larger than the surface area of the free area 121 of the deformable diaphragm 12 shown in the same figures.

In general, the deformable diaphragm 12 is preferably configured such that its free area 121 is capable of being deformed with an amplitude of less than 1 mm.

The deformation amplitude of the free area 121 is measured along a direction perpendicular to the plane in which the outer face 12e of the diaphragm 12 at rest mainly extends.

Without tearing and/or significant wear, the electromechanical microsystem 1 allows for hydraulic amplification of the action and thus offers the ability to meet the requirements of many different applications requiring a large amount of travel. In this context, the electromechanical microsystem 1 according to each of the two embodiments described above can be defined as an actuator with large upwards or downwards travel.

Still when the partial overlap of the deformable diaphragm 12 by the two electromechanical transducers is as shown in FIGS. 1B and 1C and that each electromechanical transducer is a piezoelectric transducer including a PZT-based piezoelectric material, but with reference to FIG. 2 discussed in more detail below, each electromechanical transducer 11a 11b more particularly includes an element forming a beam 305 and a PZT-based piezoelectric element 302, with the latter being configured to cause deflection of the beam 305. The thickness of the piezoelectric element 302 is, for example, substantially equal to 0.5 μm and the thickness of the beam 305 is, for example, between a few μm and several tens of μm, for example, 5 μm.

However, the invention is not limited to the various specific values given above, which can be largely adjusted, depending on the intended application, in particular to obtain a compromise between stretch factor and expected deformation amplitude of the free area 121 of the deformable diaphragm 12.

Note that, in particular when one of the electromechanical transducers is a piezoelectric transducer, it can advantageously be a transducer with a vibratory operation. Its resonant frequency is then preferably lower than 100 kHz, and even more preferably lower than 1 kHz. The vibratory dynamics thus obtained can make it possible to achieve greater deflections than in static operation, in particular by using the related resonance phenomenon, or to reduce the consumption of the electromechanical microsystem for a given deflection.

As already mentioned above, the electromechanical microsystem 1 may further comprise one or more lateral stops 15 supported by the wall 131 of the cavity 13. Each side stop 15 extends more particularly away from the cavity 13.

Relative to at least one of the side stops 15, the pin 122 may extend beyond or within the cavity 13 (see FIG. 2). The lateral stop 15 surrounding the free area 121 may also be configured to allow the external member 2 to be guided and self-positioned on the electromechanical microsystem 1. It further contributes to limiting, or even eliminating, the risk of the deformable diaphragm 12 being torn off when the external member 2 is transferred to the electromechanical microsystem 1. It should be noted here that, depending on the extension of the external member 2, it may also act as an upper stop limiting the movement of the external member 2 towards the electromechanical microsystem 1. This feature may also cause the pin 122 and the external member 2 to disengage from each other by pulling the pin 122 to a lower position than the one that the external member 2 may have reached due to the fact that the latter abuts against the top of the lateral stop 15. More specifically, such a lateral stop 15 has a stop surface area configured to stop the movement of the member 12. The electromechanical microsystem 1 is configured so that, when the movement of the member 12 is stopped, in a given direction, by the lateral stop 15, the pin 122 can continue its movement, in the same direction. The pin 122 thus disengages from the member 12.

As shown in each of FIGS. 1A and 2, the electromechanical microsystem 1 may further comprise one or more so-called bottom stops 16 supported by the wall 132 of the cavity 13 that is opposite the wall 131 formed at least in part by the deformable diaphragm 12 and extending into the cavity 13 toward the free area 121 of the deformable diaphragm 12. This bottom stop 16 preferably has a shape and dimensions configured to limit the deformation of the free area 121 of the deformable diaphragm 12 so as to protect the deformable diaphragm 12, and more particularly its free area 121, from any possibility of being torn off, in particular when the external member 2 is transferred to the electromechanical microsystem 1. Alternatively or cumulatively, the bottom stop 16 is shaped to limit the contact area between the diaphragm 12 and the wall 132 of the cavity 13 opposite the free area 121 of the deformable diaphragm 12. This prevents the diaphragm 12 from adhering to this wall 132.

A more specific embodiment of the invention than the one described above is shown in FIG. 2, in which the same references as in FIGS. 1A and 1B refer to the same objects.

First, it is observed that each electromechanical transducer 11a, 11b shown includes a beam 305 and a piezoelectric material 302 configured to deform the beam 305 when an electrical current flows through it. More particularly, the transducers 11a and 11b share a common beam 305, with their piezoelectric elements 302 being arranged opposite different areas of the beam 305. It is understood that the piezoelectric element 302 of the first transducer 11a is designed to primarily deform a central area of the beam 305, whereas the piezoelectric element 302 of the second transducer is designed to primarily deform an area of the beam 305 around the said central area.

FIG. 2 also shows the different heights that the pin 122 may have in relation to the height of the lateral stop 15 that surrounds the area 121. It is still apparent that the side stops 15 and the bottom stops 16, and/or their section, may take on different shapes, and in particular a parallelepipedal shape, a truncated cone shape, a substantially pyramidal shape, etc.

It is further apparent from FIG. 2 that the moving part 111a, 111b of each electromechanical transducer 11a, 11b may be substantially defined by the extension of the piezoelectric element 302 relative to the extension of the beam 305.

FIG. 2 also shows access openings for an electrical connection of the electrodes. These openings in these examples form vias 17. In this example, the vias 17 extend through the entire thickness of the beam 305. The thickness e₃₀₅ of the beam 305 is measured along a direction perpendicular to the plane in which the faces 12e and 12i of the diaphragm 12 mainly extend. The thickness e₃₀₅ is referenced in FIG. 2.

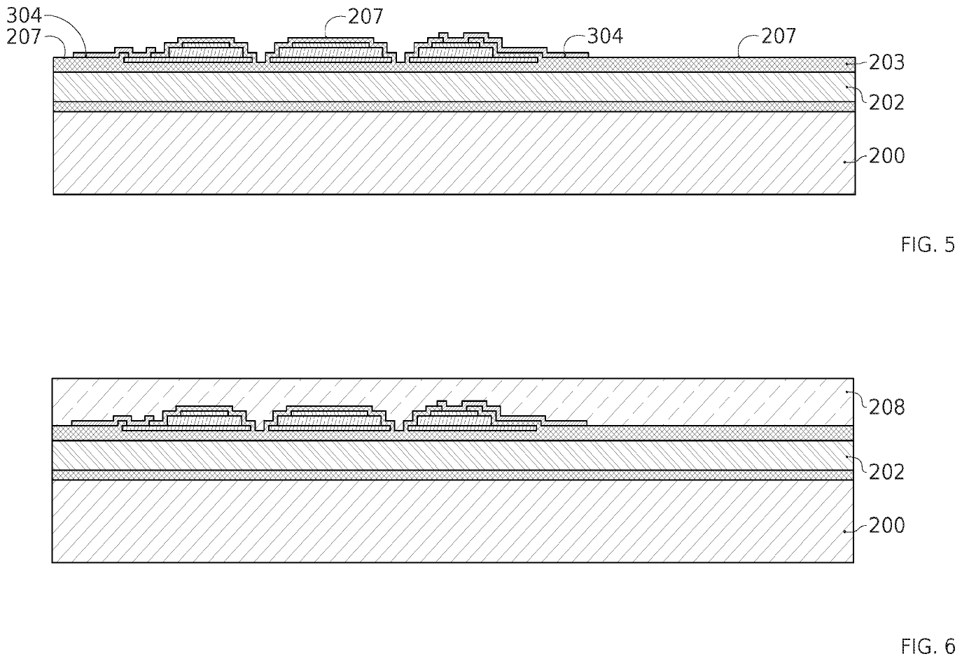

FIG. 2 shows more particularly, than do FIGS. 1A and 1B, the first embodiment of the invention already discussed above. In particular, FIG. 2 shows the first embodiment of the invention as obtained by the deposition and etching steps that may be characterised as ordinary in the microelectronics field (and this may also be the case for the second embodiment of the invention). More particularly, the electromechanical microsystem 1 according to the first embodiment shown in FIG. 2 was obtained by the succession of steps shown in FIGS. 3, 4, 5, 6, 7, 8 and 9. Thus, a manufacturing process is shown that leads to the electromechanical microsystem 1 shown in FIG. 2.

This manufacturing process includes at least:
a step involved in forming what is to be at least a portion of each electromechanical transducer 11a, 11 b on a substrate 200, and then
a step involving the deposition of the deformable diaphragm 12, and then
a step involving the forming of an open cavity 13 on the deformable diaphragm 12, and then
a step involving the filling with the deformable medium and the closing of the cavity 13, and
a step involving the etching of the substrate 200 to form the front of the electromechanical microsystem shown in FIG. 2.

The stops above manufacturing process of the electromechanical microsystem 1 as shown in FIG. 2 are described in turn below.

The first step in this process is shown in FIG. 3. It involves providing a substrate 200 having a stack of layers extending thereon which may include the following, in succession, from one side of the substrate 200:
a first insulating layer 201, for example, based on silicon oxide, which can be deposited by plasma-enhanced chemical vapour deposition (PECVD),
a layer 202 intended to form the beam 305 of the electromechanical transducers 11a and 11b, this layer 202 being, for example, based on amorphous, polycrystalline or monocrystalline silicon, and being able to be deposited by chemical vapour deposition (or CVD) at sub atmospheric pressure (or LPCVD), or by using a structure of the SOI (“Silicon On Insulator”) type,
a second insulating layer 203, for example, based on silicon oxide and which can be deposited by PECVD,
a layer 204 intended to form a so-called bottom electrode, for example, based on platinum and capable of being deposited by physical vapour deposition (PVD),
a layer 205 of a piezoelectric material, for example, based on PZT, which can be deposited by a sol-gel process, and
a layer 206 intended to form a so-called top electrode, for example, based on platinum and able to deposited by PVD.

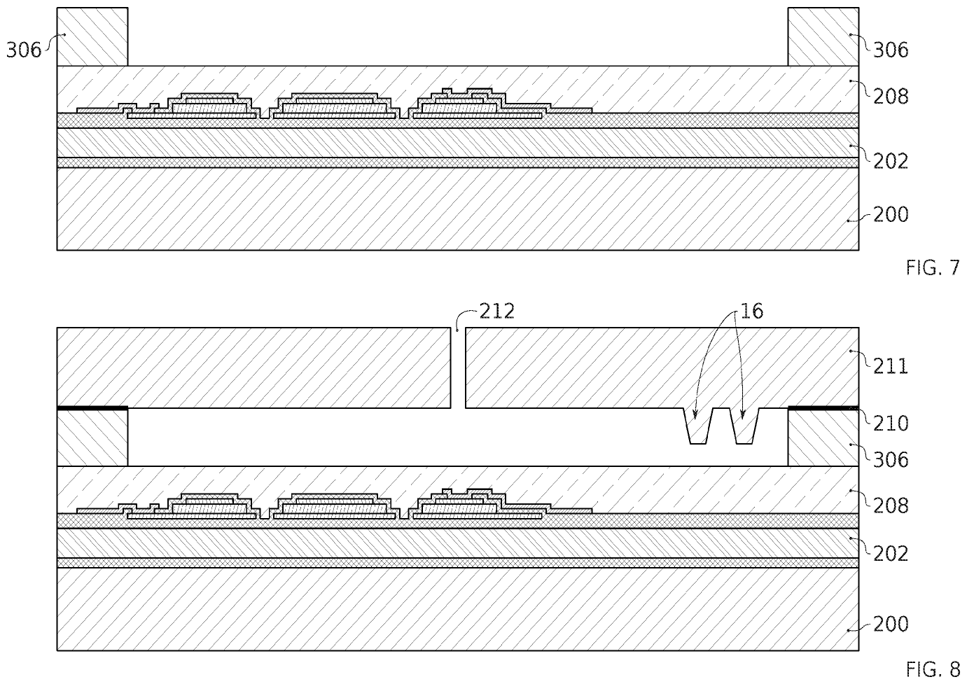

The second step in the manufacturing process of the electromechanical microsystem 1 as shown in FIG. 2 is shown in FIG. 4. They include:
etching the layer 206 to form the top electrode 301 of each electromechanical transducer 11a, 11b,
etching the layer 205 to form the piezoelectric elements 302 of the electromechanical transducers 11a, 11 b, and
etching the layer 204 to form the bottom electrode 303 of each electromechanical transducer 11a, 11b.

Note that each of these etching processes can be carried out by lithography, and preferably by plasma etching, or through a wet chemical process.

The third step in the manufacturing process of the electromechanical microsystem 1 as shown in FIG. 2 is shown in FIG. 5. They include:
the deposition of a passivation layer 207, for example, based on silicon oxide and/or silicon nitride, which can be deposited by PECVD,
opening, through the passivation layer 207, of an electrode contact recovery area, this opening being carried out, for example, by lithography, and preferably by plasma etching, or through a wet chemical process,
the deposition a layer intended to form an electrical line 304 per electrode, the layer being, for example, gold-based and being able to be deposited by PVD, and
etching of the previously deposited layer so as to form an electrical line 304 per electrode, this etching being carried out, for example, by lithography, and preferably by plasma etching, or through a wet chemical process.

The fourth step in the manufacturing process of the electromechanical microsystem 1 as shown in FIG. 2 is shown in FIG. 6. It includes the deposition of a polymer-based layer 208 and intended to form the deformable diaphragm 12. This layer 208 is, for example, deposited by spin coating. The polymer from which the layer 208 is formed is, for example, PDMS based.

The fifth step in the manufacturing process of the electromechanical microsystem 1 as shown in FIG. 2 is shown in FIG. 7. It includes the forming of at least one spacer 306 to form at least a part of the said at least one side wall 133 of the cavity 13. The formation of the spacer(s) may include the laminating of a photosensitive material from which the spacer(s) is(are) formed, exposing it, and then developing the photosensitive material. The said photosensitive material may be polymer based, and in particular Siloxane based. Laminating the photosensitive material may include laminating a dry film of the said material.

The sixth step in the manufacturing process of the electromechanical microsystem 1 as shown in FIG. 2 is shown in FIG. 8. According to an optional embodiment, this step includes the deposition of adhesive 210 on top of each spacer 306, this deposition being able to be accomplished by screen printing or by dispensing. It comprises the fastening, for example, by bonding, to the top of the spacer(s) (through adhesive, if applicable), a second substrate 211 which may be structured to include at least one through vent 212 and a bottom stop 16 as described above. In an alternative embodiment, depending on the type of spacer, the spacer may act as an adhesive. At the end of this sixth step, the cavity 13 is formed which is opened by at least one through vent 212.

The seventh step in the manufacturing process of the electromechanical microsystem 1 as shown in FIG. 2 is shown in FIG. 9. It includes the filling, preferably under vacuum conditions, of the cavity 13 with the deformable medium 14 as described above, for example by dispensing through the at least one through vent 212. It also includes sealing the at least one through vent 212, for example, by dispensing a sealing material 213 at the mouth of each through vent 212, with the sealing material 213 being, for example, epoxy adhesive based.

The eighth step in the manufacturing process of the electromechanical microsystem 1 as shown in FIG. 2 is the step for obtaining it. It includes the etching of the substrate 200. This etching can be carried out by lithography, preferably by plasma etching, or through a wet chemical process. It then includes etching the layer 202 and the insulating layers 201, 203 so as to form at least one beam 305 of the electromechanical transducers 11a, 11 b, exposing a part of the deformable diaphragm 12, and forming all or part of the pin 122, the cover 18 and any side stops 15.

Note that, following the above-described steps of manufacturing the electromechanical microsystem 1 as shown in FIG. 2, the pin 122 takes the form of a stack extending directly from the deformable diaphragm 12 away from the cavity 13 with successively the insulating layer material 201, the material forming the beam 305, the insulating layer material 203 and the material forming the substrate 200. It should also be noted that, following the above-described steps of manufacturing the electromechanical microsystem 1 as shown in FIG. 2, the possible side stops 15 each take the form of a stack extending, directly or indirectly, from the deformable diaphragm 12 away from the cavity 13 with successively the material of the insulating layer 201, the material forming the beam 305, the material of the insulating layer 203 and the material forming the substrate 200.

It should also be noted that the cover 18 discussed above is also formed by carrying out the technological steps shown in FIGS. 3 to 9. The cover 18 and takes the form of a structured stack extending partly directly and partly indirectly from the deformable diaphragm 12 away from the cavity 13 with successively the material of the insulating layer 201, the material forming the beam 305 and the material of the insulating layer 203. The part of the cover 18 extending indirectly from the diaphragm 12 overlap the non-moving part of the second electromechanical transducer 11b.

It should be noted here that, if the cover 18 is not necessarily as thick as the said at least one lateral stop 15 (which itself potentially has a role of limiting the travel of the pin 122, unlike the cover 18), it is however, possible, in order to increase the rigidity of the cover 18, if necessary, and/or to better secure the non-moving parts of the transducers, for the cover 18 to have the same composition and the same thickness extension as the said at least one lateral stop 15. The two are then indissociable from each other.

Another aspect of the invention relates to an opto-electromechanical system 3 as shown in FIGS. 10A, 10B, 11A and 11B. This may be an opto-electromechanical microsystem 3. Each of the opto-electromechanical microsystems 3 shown in these figures includes at least one electromechanical microsystem 1 as described above and at least one optical microsystem 31. The said at least one electromechanical microsystem 1 is preferably mounted on a support 32 of the opto-electromechanical microsystem 3. The said at least one optical microsystem 31 may comprise a silicon-based micromirror, the surface of which may be topped with at least one mirror. It may be mounted directly on the said at least one electromechanical microsystem 1 or mounted thereon via a frame 33. It may have dimensions substantially equal to 2 mm×5 mm and/or, at most, a thickness of about 700 μm. The opto-electromechanical microsystems 3 as shown each comprise four electromechanical microsystems 1 each having a free area 121 arranged opposite a part of the same optical microsystem 31, this part being specific and preferably a corner of the said optical microsystem 31 or of its centre. This results in an opto-electromechanical microsystem 1 with a large capacity to adapt its optical orientation.

It should also be noted that, because of the possibility offered by each electromechanical microsystem 1 according to the invention of acting on the optical microsystem 31 by moving it alternately upwards and downwards, the achievable angles of tilt of the optical microsystem 31 are thus advantageously increased by an amplitude, relative to electromechanical microsystems which allow the optical microsystem 31 to be acted on in only one direction, upwards or downwards.

It should be further noted that, due to the decentring of the free area 121 of the deformable diaphragm 12 relative to the area 123 over which the electromechanical transducers 11a and 11b extend, it is possible to arrange the free areas 121 of the four electromechanical microsystems 1 as close as possible to the corners or centre of the optical microsystem 31, and in particular potentially closer than would be possible with electromechanical microsystems in each of which the free area 121 of the deformable diaphragm 12 would be centred on the area 123 of the electromechanical transducers. The achievable tilt angles of the optical microsystem 31 are thus advantageously of an increased amplitude.

The invention is not limited to the previously described embodiments and extends to all embodiments covered by the claims.

In particular, other applications than those described above are possible. For example, the electromechanical microsystem 1 can be arranged in a micropump, or even in a micropump array system, in a haptic system, or in a vibratory and possibly acoustic diaphragm system.

1. An electromechanical microsystem comprising:
at least two electromechanical transducers each comprising a part moving between an equilibrium, non-loaded position and an out-of-equilibrium, loaded position,
at least one deformable diaphragm, and
a deformable cavity bounded by walls, at least part of the deformable diaphragm forming at least part of a first wall of the walls of the cavity, the cavity hermetically containing a deformable medium maintaining a substantially constant volume under an action of a change in external pressure exerted on the deformable medium through one of the walls of the cavity, wherein
the moving part of each electromechanical transducer is configured to move as a function of the change in external pressure, or conversely to move causing a change in external pressure, and wherein the at least one part of the deformable diaphragm is provided with at least one area free to deform, depending on the change in external pressure,
the moving part of at least a first electromechanical transducer is configured so that acting upon it or an increase in external pressure causes movement towards the outside of the cavity, and
the moving part of at least a second electromechanical transducer is configured so that acting upon it or a decrease in external pressure causes its movement towards the inside of the cavity, and
the at least two electromechanical transducers extend, on one of the same walls chosen from the walls of the cavity at a distance from the free area of the deformable diaphragm.

2. The electromechanical microsystem according to claim 1, wherein the at least one first electromechanical transducer comprises at least one first disc-shaped electromechanical transducer of radius R1 and the at least one second electromechanical transducer comprises at least one second ring-shaped electromechanical transducer with a radial extension of R2.

3. The electromechanical microsystem according to claim 2, wherein
the at least one first electromechanical transducer and the at least one second electromechanical transducer are contained within boundaries of a circular area of given radius, known as and a total radius and noted Rₜₒₜ, with the circular area consisting of two parts:
a first part shaped like a disc centred on the circular area, and
a second part shaped like a ring extending around the first part,
the at least one first electromechanical transducer is contained within the first part of the circular area and at the least one second electromechanical transducer is contained within the second part of the circular area, and
the first part of the circular area has a radius R_{2/3} substantially equal to two thirds of the total radius and the second part of the circular area has a radial extension E_{1/3} substantially equal to one third of the total radius.

4. The electromechanical microsystem according to claim 3, wherein at least one of:
the at least one first electromechanical transducer further comprises at least one first ring-shaped electromechanical transducer, each first ring-shaped electromechanical transducer extending around the first disc-shaped electromechanical transducer and around another first ring-shaped electromechanical transducer, and
the said at least one second electromechanical transducer comprises a plurality of second electromechanical transducers each ring shaped and being arranged adjacent to and concentric with each other.

5. The electromechanical microsystem according to claim 3, wherein the at least one first electromechanical transducer comprises one first disc-shaped electromechanical transducer of radius R1 and the at least one second electromechanical transducer comprises one second ring-shaped electromechanical transducer with a radial extension of R2.

6. The electromechanical microsystem according to claim 5, wherein the radial extension R2 of the ring formed by the second electromechanical transducer is about twice as small as the radius R1 of the disc formed by the first electromechanical transducer.

7. The electromechanical microsystem according to claim 5, wherein the radius R1 of the disc formed by the first electromechanical transducer is at most equal to ⅔ of a sum of the radius R1 of the disc formed by the first electromechanical transducer and the radial extension R2 of the ring formed by the at least one second electromechanical transducer, and the radial extension R2 of the ring formed by the second electromechanical transducer is at most equal to ⅓ of the sum of the radius R1 of the disc formed by the first electromechanical transducer and the radial extension R2 of the ring formed by the second electromechanical transducer.

8. The electromechanical microsystem according to claim 1, wherein the at least two electromechanical transducers are concentric.

9. The electromechanical microsystem according to claim 1, wherein, the free area is configured to cooperate with at least one external member so that its deformation causes, or is caused by, a movement of the external member, the free area of the deformable diaphragm is configured to cooperate with the external member via a pin attached to the free area in contact with the free area.

10. The electromechanical microsystem according to claim 1, wherein at least part of the said at least two electromechanical transducers forms a part of the said first wall of the cavity.

11. The electromechanical microsystem according to claim 10, wherein the at least two electromechanical transducers extend, directly or indirectly, over the deformable diaphragm.

12. The electromechanical microsystem according to claim 1, wherein the at least one second electromechanical transducer is configured such that a movement of its moving part from its equilibrium position to its non-equilibrium position causes an increase in the external pressure acting on the deformable medium and wherein the deformable diaphragm is configured such that an increase in the external pressure acting on the deformable medium causes a deformation of the free area of the deformable diaphragm tending to move it away from a second wall of the cavity, with the second wall being different from the first wall and remaining fixed when the deformable diaphragm is deformed.

13. The electromechanical microsystem according to claim 1, wherein the at least one first electromechanical transducer can be configured such that a movement of its moving part from its equilibrium position to its non-equilibrium position causes a decrease in the external pressure acting on the deformable medium and wherein the deformable diaphragm is configured such that a decrease in the external pressure acting on the deformable medium causes a deformation of the free area of the deformable diaphragm tending to move it towards at least a second wall of the cavity, with the second wall being different from the first wall and remaining fixed when the deformable diaphragm is deformed.

14. The electromechanical microsystem according to claim 1, wherein the deformable diaphragm is configured such that its free area is capable of being deformed with an amplitude of at least 50 μm.

15. The electromechanical microsystem according to claim 1, wherein, the moving part of each electromechanical transducer has a surface area at least twice as large as a surface area of the free area of the deformable diaphragm.

16. The electromechanical microsystem according to claim 1, wherein each electromechanical transducer is a piezoelectric transducer comprising a PZT-based piezoelectric material.

17. The electromechanical microsystem according to claim 1, wherein at least one of the at least two electromechanical transducers is a statically-operating transducer.

18. The electromechanical microsystem according to claim 1, wherein at least one of the at least two electromechanical transducers is a vibratory-operating transducer with at least one resonant frequency, the at least one resonant frequency being less than 100 kHz.

19. The electromechanical microsystem according to claim 1, wherein the deformable medium hermetically contained in the cavity comprises at least one fluid.

20. An opto-electromechanical system including at least one electromechanical microsystem according to claim 1 and at least one optical microsystem.

21. The opto-electromechanical system according to claim 20, wherein the at least one optical microsystem includes at least one mirror, the opto-electromechanical system being configured such that the movement of the moving part of each of the at least two electromechanical transducers causes a movement of the at least one mirror.

22. The opto-electromechanical system according to claim 20, comprising a plurality of the electromechanical microsystems and each having a free area arranged opposite a part of the same optical microsystem.

23. A process of manufacturing an electromechanical microsystem according to claim 1, including:
forming, on a substrate, at least a portion of at least two electromechanical transducers, and then
depositing the deformable diaphragm, and then
forming an open cavity on the deformable diaphragm, and then
filling with the deformable medium and closing of the cavity, and
etching the substrate to form a front face of the electromechanical microsystem.
